(19) United States
(12) Patent Application Publication
(10) Pub. No.: US 2014/0374151 A1
(43) Pub. Date: Dec. 25, 2014

(54) WIRE BONDING METHOD FOR FLEXIBLE SUBSTRATES

(71) Applicants: Jia Lin Yap, Klang (MY); Poh Leng Eu, Petaling Jaya (MY); Ahmad Termizi Suhaimi, Machang (MY)

(72) Inventors: Jia Lin Yap, Klang (MY); Poh Leng Eu, Petaling Jaya (MY); Ahmad Termizi Suhaimi, Machang (MY)

(21) Appl. No.: 13/924,626

(22) Filed: Jun. 24, 2013

(51) Int. Cl. H01R 43/02; H01R 43/28; B23K 1/00; H05K 1/11

(52) U.S. Cl. CPC H01R 43/0256; H05K 1/118; H01R 43/28; B23K 1/0016; B23K 2001/12
USPC 174/261; 228/103; 228/15.1

(57) ABSTRACT

A wire bonded electrical interconnection includes a first electrical contact, a second electrical contact, and a bond wire having a first end bonded to the first electrical contact, a second end bonded to the second electrical contact, and a central portion connecting the first and second ends. The central portion includes notches formed during a wire bonding process, with each notch having at least two corners.

### BACKGROUND OF THE INVENTION

The present invention is directed to a method of wire bonding electrical contacts and, more particularly, to a method of wire bonding electrical contacts on flexible substrates.

Electronic devices such as smart phones, tablets, and the like are trending toward being flexible for a myriad of reasons. In addition, electronic devices have become more compact, and less space is available in manufacturing for the placement of electronics and circuitry. Thus, the use of flexible substrates and chips has become more commonplace in the industry.

However, standard wire bonds are not particularly suitable for use with flexible chips. Stresses on the wire loop, the bond at the bond pad, and the stitch bond at the lead contact can be too great due to the flexibility of the substrate, which can lead to breakage of the bond wire or wire bond. In addition, electrical interconnection through solder balls is not a suitable method for use with flexible substrates.

It is therefore desirable to provide a method of electrically interconnecting electrical contacts on a flexible substrate that will minimize stresses and reduce breakage of the bond wire, and which will add few additional steps or components to the wire bonding process.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. Notably, certain vertical dimensions have been exaggerated relative to certain horizontal dimensions.

In the drawings:

FIG. 1 is a side perspective view of an electrical interconnection in accordance with an embodiment of the invention;

FIG. 2 is a schematic view of an embodiment of a wire bonder for use in forming the electrical interconnection of FIG. 1;

FIG. 3 is an enlarged top plan view of a wire shaping tool from the wire bonder of FIG. 2; and

FIG. 4 is a partial schematic view of an alternate embodiment of a wire bonder for use in forming the electrical interconnection of FIG. 1.

### DETAILED DESCRIPTION OF THE INVENTION

Referring to the drawings, wherein the same reference numerals are used to designate the same components throughout the several figures, there is shown in FIG. 1 an electrical interconnection 10 in accordance with a preferred embodiment of the invention. A first electrical contact 12 is provided, preferably on a substrate 14 or some other form of support. The substrate 14 may be made from flexible materials, such as polyimide, polyether ether ketone (PEEK), polyester, other flexible polymer-based materials, or the like, and may have a thickness in the range of about 0.2 to about 0.4 millimeters (mm) in exemplary embodiments.

The first electrical contact 12 may be, as shown in the example of FIG. 1, in the form of a bond pad on the substrate 14. The bond pad 12 may be made from copper (Cu) and/or other conductive materials, and may be coated, alloyed or pre-plated with a metal layer or layers such as gold (AU), nickel (Ni), palladium (PD), tin (Sn) or the like.

A second electrical contact 16 may also be provided. Although the second electrical contact 16 is shown in FIG. 1 as being located on the same substrate 14 as the first electrical contact 12, the two contacts 12, 16 may alternatively be disposed on different substrates 14 or supports. In the example of FIG. 1, the second electrical contact 16 is in the form of a conventional lead, for a semiconductor package or the like, and may be made of copper that is coated, alloyed or pre-plated with a metal layer or layers such as gold, nickel, palladium, tin, or the like. However, other like conductive materials may be used to form the second electrical contact 16.

The first and second electrical contacts 12, 16 are electrically interconnected with a bond wire 18. The bond wire is preferably made from gold, although other conductive materials such a copper or aluminium may be used as well. At least a portion of the bond wire 18 may also include an insulating coating (not shown), which can be an insulating organic or polymeric material surrounding at least a portion of the conductive core.

The bond wire 18 includes a first portion 18a that is attached to the first electrical contact 12. A first bond 20 at the first electrical contact 12 is preferably a ball bond, which may be formed by forming a ball at an end of the bond wire 18 with a hydrogen flame or a spark and pressing it against the first electrical contact 12 by a capillary 58 (FIG. 2) holding the bond wire 18. Next, thermocompression, thermosonic or ultrasonic wire bonding is performed to bond the first portion 18a of the bond wire 18 to the first electrical contact 12. However, other conventional methods of forming the first bond 20 may also be used.

The bond wire 18 further includes a second portion 18b that is attached to the second electrical contact 16. A second bond 22 at the second electrical contact 16 is preferably in the form of a stitch bond. The second bond also may include a security bond formed over the stitch bond. The stitch bond may be formed by pressing the second portion 18b of the bond wire 18 against the second electrical contact 16 by the capillary 58 (FIG. 2), and performing thermocompression, thermosonic or ultrasonic wirebonding to bond the metal of the bond wire 18 to the second electrical contact 16. The capillary 58 is then lifted off of the second electrical contact 16, which breaks the bond wire 18. In one embodiment, a ball bump is thereafter welded over top of the stitch bond using conventional techniques to complete the second bond 22.

The bond wire 18 further includes a third portion 18c that connects the first and second portions 18a, 18b together. The third portion 18c is formed of a plurality of bent sections that form notches 24, which better enables the bond wire 18 and the first and second bonds 20, 22 to alleviate stresses from elongation and compression through flexing of the substrate 14 or bond wire 18. Each notch 24 is defined by at least two corners 26, which are locations where adjacent lengths of the bond wire 18 meet at a generally right angle.

For example, FIG. 1 shows the notches 24 as each having a generally rectangular shape, defined by four corners 26 each having an angle of about 90 degrees. Although this configuration is preferred for its rigidity, other shapes for the notches may also be used. For example, the notches 24 may take the shape of triangles, each defined by three corners 26. The notches 24 may also have two corners 26 with a curve extending therebetween. Other shapes, including irregular shapes and configurations can be used as well. The notches 24 are also shown in FIG. 1 as being periodic and evenly spaced apart from one another. However, the present invention also contemplates that the shapes of the notches 24 need not correspond to one another and no periodicity or set spacing is required.

Multiple bond wires 18 having notch configurations can be used to string together multiple electrical contacts (not shown) in series or in parallel.

Referring now to FIG. 2, a wire bonder 50 that may be used for making the electrical interconnection 10 of FIG. 1 is shown. The wire bonder 50 includes a bond wire supply or feed 52, which is typically a spool of the bond wire 18. An air guide 54 receives the bond wire 18 from the feed 52 and is provided to ensure a smooth and continuous wire supply to the downstream components. A tensioner 56 may be provided to supply a constant, pre-determined amount of tension to the bond wire 18 during predetermined timeframes of a wire bonding cycle. A capillary 58 is provided to receive the bond wire 18 for application to a bonding site (i.e., the first or second electrical contact 12, 16). Other components may be provided for the wire bonder 50 as is conventionally known.

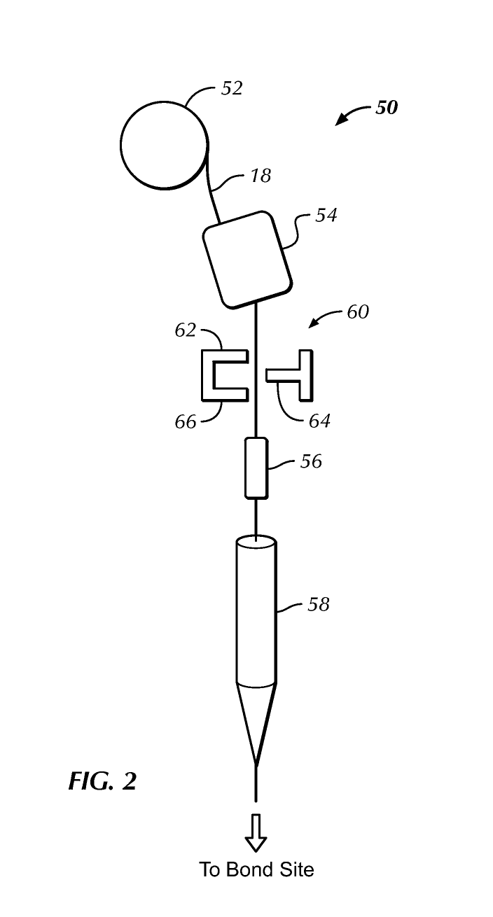

A wire shaping tool 60 is provided for forming the notches 24 within the third portion 18c of the bond wire 18. In a preferred embodiment, the wire shaping tool 60 includes at least a first die 62 and a second die 64 spaced apart from one another along a feed direction of the bond wire 18 and disposed on opposite sides of the bond wire 18. The first and second dies 62, 64 are repetitively moved into and out of a feed path of the bond wire 18 to shape the third portion 18c of the bond wire 18 into the plurality of notches 24 (see e.g., FIG. 4).

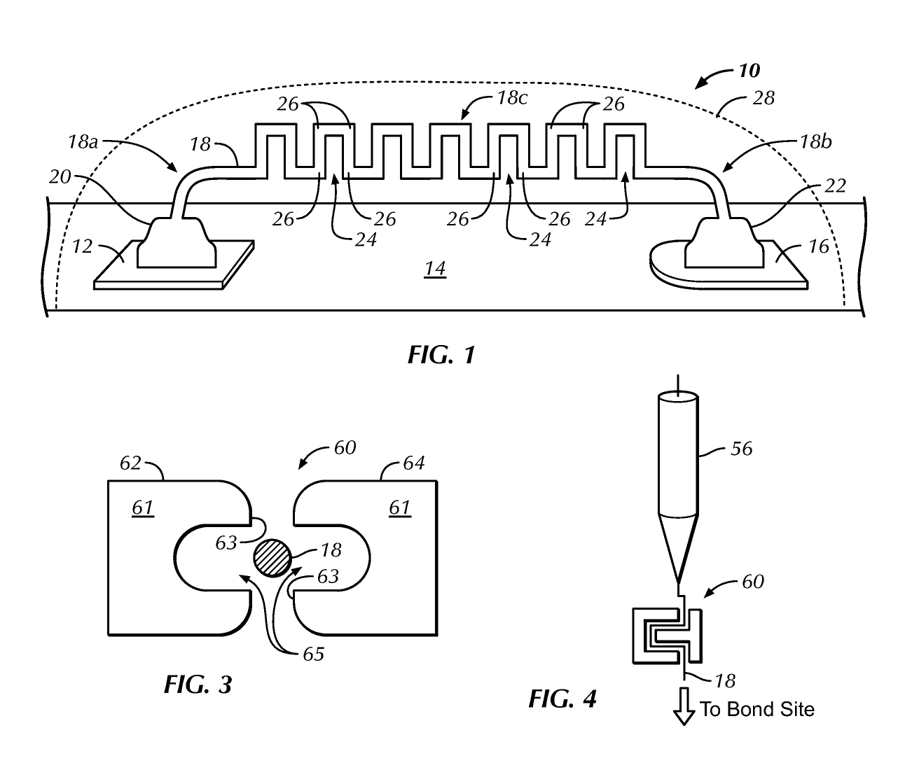

FIG. 3 is a top plan view of the first and second dies 62, 64 and shows that each die 62, 64 is in the form of a plate 61 including an edge 63 facing the bond wire 18. An opening 65 is formed in each edge 63 facing the bond wire 18 for providing the desired shape for the notches 24. The dies 62, 64 are preferably made from halide-free composite, ceramic, polymeric, metal, or like materials.

More preferably, as shown in FIG. 2, a third die 66 similar to the first and second dies 62, 64 is also provided for creating the rectangular shape of the notches 24 shown in FIG. 1. The third die 66 is spaced apart from both the first and second dies 62, 64 along the feed direction of the bond wire 18 and is disposed on an opposing side of the bond wire 18 from the second die 64. The first and third dies 62, 66 are preferably coupled together, although this is not required.

The wire shaping tool 60 is disposed between the bond wire feed 52 and the bonding site 12, 16. More particularly, the wire shaping tool 60 is shown in FIG. 2 as being disposed between the bond wire feed 52 and the capillary 58, specifically between the air guide 54 and the tensioner 56, although other locations are contemplated by the invention. Alternatively, FIG. 4 shows the wire shaping tool 60 disposed between the capillary 58 and the bonding site 12, 16.

Preferably, one or more components of the wire bonder 50 are in operative communication with a processor (not shown) which is programmed or configured to calculate the length of the bond wire 18 necessary for the formation of each interconnection 10, identify the first, second, and third portions 18a, 18b, 18c of the bond wire 18 along the calculated length, and prompt the wire shaping tool 60 to move in and out of the feed path of the bond wire 18 as the third portion 18c passes therethrough.

Referring again to FIG. 1, the first and second electrical contacts 12, 16 and the bond wire 18 may be encapsulated or covered with a halide-free elastomeric or soft and flexible polymeric material 28 (in phantom). The cover material 28 is used to provide additional flexibility during bending or compression of the bond wire 18 and/or substrate 14. The cover material 28 may be applied by conventional deposition, coating, or spin-on, or other techniques.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and the order of operations may be altered in various other embodiments.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, the word ‘comprising’ or ‘having’ does not exclude the presence of other elements or steps then those listed in a claim. Further, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A wire bonded electrical interconnection comprising:
a first electrical contact;
a second electrical contact; and
a bond wire having a first portion bonded to the first electrical contact, a second portion bonded to the second electrical contact, and a third portion connecting the first and second portions, wherein a plurality of notches are formed by the third portion of the bond wire, each of the plurality of notches being defined by at least two corners

2. The wire bonded electrical interconnection of claim 1, wherein each notch has a generally rectangular shape.

3. The wire bonded electrical interconnection of claim 1, wherein the first and second electrical contacts and the bond wire are covered by an elastomeric material.

4. The wire bonded electrical interconnection of claim 1, wherein an angle of each corner is about 90 degrees.

5. The wire bonded electrical interconnection of claim 1, wherein the second portion of the wire is bonded to the second contact by a stitch bond with a security bond.

6. The wire bonded electrical interconnection of claim 1, wherein at least one of the first and second electrical contacts is formed on a flexible substrate.

7. A method of making an electrical interconnection between a first electrical contact and a second electrical contact, the method comprising:
passing a bond wire through a wire bonding system;
identifying a first portion of the bond wire to be bonded to the first electrical contact, a second portion of the bond wire to be bonded to the second electrical contact, and a third portion of the bond wire connecting the first and second portions;
forming a plurality of notches with the third portion of the bond wire using a wire shaping tool to form corners defining the notches, each notch being defined by at least two corners;
bonding the first portion of the bond wire to the first electrical contact; and
bonding the second portion of the bond wire to the second electrical contact.

8. The method of claim 7, wherein the wire bonding system includes a capillary through which the wire bond passes, and wherein the step of forming the notches occurs before the wire bond passes through the capillary

9. The method of claim 7, wherein the wire bonding system includes a capillary through which the wire bond passes, and wherein the step of forming the notches occurs after the wire bond passes through the capillary.

10. The method of claim 7, wherein each of the plurality of notches is formed to have a generally rectangular shape.

11. The method of claim 7, wherein the corners are formed to have angles of about 90 degrees.

12. The method of claim 7, wherein the bonding of the first portion of the bond wire to the first electrical contact includes forming a ball bond.

13. The method of claim 7, wherein the bonding of the second portion of the bond wire to the second electrical contact includes forming a security bond over a stitch bond.

14. A wire bonding system comprising:
a bond wire feed supplying a bond wire;
a capillary that receives the bond wire for application to a bonding site; and
a wire shaping tool disposed between the bond wire feed and the bonding site and configured to form notches within a portion of the bond wire by forming corners in the portion of the bond wire, each notch being defined by at least two corners.

15. The system of claim 14, wherein the wire shaping tool includes a first die and a second die, the first and second dies being spaced apart from each other along a feed direction of the bond wire and being disposed on opposing sides of the bond wire.

16. The system of claim 15, wherein at least one of the first and second dies is in the form of a plate having an edge facing the bond wire and an opening formed in the edge facing the bond wire.

17. The system of claim 15, wherein the wire shaping tool further includes a third die spaced apart from the first and second dies along the feed direction of the bond wire and disposed on an opposing side of the bond wire from the second die.

18. The system of claim 14, wherein the wire shaping tool is disposed between the bond wire feed and the capillary.

19. The system of claim 14, wherein the wire shaping tool is disposed between the capillary and the bonding site.
